(19) United States
(12) Patent Application Publication
(10) Pub. No.: US 2008/0185682 A1
(43) Pub. Date: Aug. 7, 2008

(54) High Voltage Metal-On-Passivation Capacitor

(75) Inventor: Martin Alter, Los Altos, CA (US)

Correspondence Address: PATENT LAW GROUP LLP, 2635 NORTH FIRST STREET, SUITE 223, SAN JOSE, CA, 95134, US

(73) Assignee: Micrel, Inc., San Jose, CA (US)

(21) Appl. No.: 11/671,882

(22) Filed: Feb. 6, 2007

(51) Int. Cl. H01L 29/92

(52) U.S. Cl. 257/532; 257/E29.343

(57) ABSTRACT

A capacitor is formed in an integrated circuit where the integrated circuit is fabricated using a fabrication process having multiple metal layers with the topmost metal layer being passivated by a passivation layer. The capacitor includes a first metal pad formed underneath the passivation layer using the topmost metal layer of the integrated circuit where the first metal pad forming the first conductive plate of the capacitor, and a second metal pad formed on the top of the passivation layer with the second metal pad being in vertical alignment with the first metal pad. The second metal pad forms the second conductive plate of the capacitor and the second metal pad is formed without an overlying passivation layer. The passivation layer sandwiched between the first metal pad and the second metal pad forms the dielectric of the capacitor.

### FIELD OF THE INVENTION

The invention relates to integrated circuit capacitors and, in particular, to an integrated circuit capacitor with one metal plate formed on the top of the passivation layer of the integrated circuit.

### DESCRIPTION OF THE RELATED ART

Capacitors are formed in semiconductor integrated circuits using the conductive and dielectric layers inherent in the integrated circuits. For example, a capacitor can be formed using the polysilicon layer as one conductive electrode, the N-well or P-well as the other conductive electrode and the field oxide layer as the dielectric. It is also known to form integrated circuit capacitors using the polysilicon layer and the first metal layer (metal1) as the conductive electrodes and the BPSG layer as the dielectric. Furthermore, integrated circuit capacitors can also be formed using two adjacent metal layers, such as the first and second metal layers, and the inter-level dielectric as dielectric.

The capacitance of a capacitor is directly proportional to the dielectric constant (or permittivity) of the dielectric material and the area of the conductive plates forming the electrodes and is inversely proportional to the thickness of the dielectric material separating the conductive plates. In some applications, a high voltage capacitor with a large capacitance value is required. To form a capacitor with a large capacitance value in a semiconductor integrated circuit, a large silicon area is required because the dielectric constant of the dielectric materials is typically very low. In most cases, it is difficult to derive enough area on an integrated circuit to form such a high-voltage capacitor.

### SUMMARY OF THE INVENTION

According to one embodiment of the present invention, a capacitor is formed in an integrated circuit where the integrated circuit is fabricated using a fabrication process having multiple metal layers with the topmost metal layer being passivated by a passivation layer. The capacitor includes a first metal pad formed underneath the passivation layer using the topmost metal layer of the integrated circuit where the first metal pad forming the first conductive plate of the capacitor, and a second metal pad formed on the top of the passivation layer with the second metal pad being in vertical alignment with the first metal pad. The second metal pad forms the second conductive plate of the capacitor and the second metal pad is formed without an overlying passivation layer. The passivation layer sandwiched between the first metal pad and the second metal pad forms the dielectric of the capacitor.

According to another aspect of the present invention, the passivation layer includes a first dielectric layer and a second dielectric layer formed over the first dielectric layer.

According to yet another aspect of the present invention, the capacitor further includes a fourth metal pad formed between the first dielectric layer and the second dielectric layer where the fourth metal pad is in vertical alignment with the first and second metal pads. As thus formed, the capacitor forms a stacked capacitor including a first capacitor formed by the first metal pad and the fourth metal pad and the first dielectric layer sandwiched therebetween and a second capacitor formed by the fourth metal pad and the second metal pad and the second dielectric layer sandwiched therebetween.

The present invention is better understood upon consideration of the detailed description below and the accompanying drawings.

### BRIEF DESCRIPTION OF THE DRAWINGS

FIG. 1 is a perspective cross-sectional view of a semiconductor integrated circuit incorporating a metal-on-passivation capacitor according to one embodiment of the present invention.

FIG. 2 is a perspective cross-sectional view of a semiconductor integrated circuit incorporating a metal-on-passivation capacitor and a metal-in-passivation capacitor according to an alternate embodiment of the present invention.

FIG. 3 is a cross-sectional view of the metal-on-passivation capacitor structure according to one embodiment of the present invention.

FIG. 4 is a cross-sectional view of the metal-on-passivation capacitor and metal-in-passivation capacitor structure according to one embodiment of the present invention.

### DETAILED DESCRIPTION OF THE PREFERRED EMBODIMENTS

In accordance with the principles of the present invention, a metal-on-passivation (MOP) capacitor is formed using the passivation layer as the dielectric and a metal layer formed on the top of the passivation layer as one conductive electrode and a metal layer underneath the passivation layer as the other conductive electrode. The metal layer formed on the top of the passivation layer remains exposed on the integrated circuit and is not further covered by another dielectric layer. In an alternate embodiment, the MOP capacitor structure further includes a metal-in-passivation capacitor to form a pair of capacitors connected either in series or in parallel.

One advantage of the MOP capacitor is that the passivation layer of a semiconductor integrated circuit typically has a higher dielectric constant than the lower level dielectrics which allows a larger capacitance value to be obtained for a given area. Furthermore, the nitride (or oxynitride) layer of a typical passivation layer structure has a higher rupture voltage which can therefore allow it to withstand high voltages reliably.

The MOP capacitor of the present invention is formed using a metal layer that is formed on the top of the passivation layer and the metal layer has no further protective covering. In conventional semiconductor integrated circuits, the passivation layer covers and protects the entire integrated circuit except for the metal bond pads. It is well known that metal layers in an integrated circuit must be covered to protect the metal layers from external elements which can cause corrosion of the metal layers. Corrosion of the metal layers can be detrimental to thin and narrow metal lines because thin metal lines may become corroded entirely to form open circuits. However, corrosion of a large metal region is not as much of a concern because of the large amount of metal present. For instance, corrosion of a small portion of a large top plate of a capacitor will not cause significant operational or reliability problems. Not covering the MOP layer with another passivation layer saves the cost of the deposition and masking steps and simplifies the fabrication process.

The inventor of the present invention recognizes the feasibility of using an exposed metal layer on the top of the passivation layer to form a capacitor with a large capacitance value. While the exposed metal layer may be subjected to corrosion from exposure to the environment, the amount of corrosion is not likely to affect the operational characteristic of the capacitor thus formed. Also, not having the MOP layer covered by a passivation layer makes the MOP layer susceptible to scratches but since the MOP layer is large and any gaps between adjacent MOP regions can be made large, scratches on the MOP layer are not a significant concern.

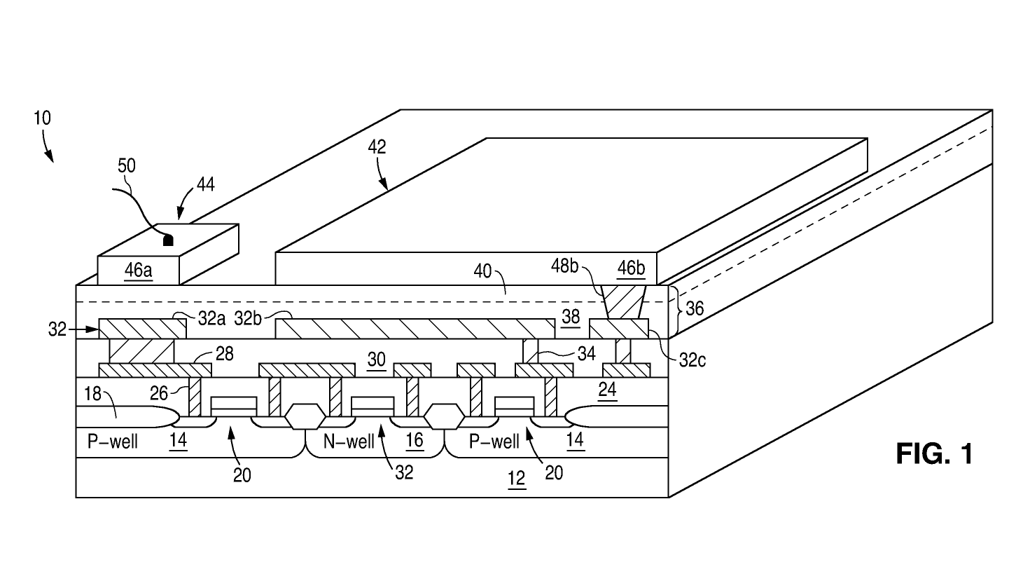

FIG. 1 is a perspective cross-sectional view of a semiconductor integrated circuit incorporating a metal-on-passivation (MOP) capacitor according to one embodiment of the present invention. Referring to FIG. 1, a semiconductor integrated circuit 10 is formed on a semiconductor substrate 12 which is a p-type substrate in the present embodiment. P-wells 14 and N-wells 16 are formed in substrate 12 using conventional fabrication methods. A field oxidation process is then carried out to form a field oxide layer 18 which defines the active area of substrate 12. In each active area, a polysilicon layer over a gate oxide layer and a pair of diffusion regions formed a transistor. NMOS transistors 20 are formed in P-wells 14 and PMOS transistors 22 are formed in N-wells 16.

A dielectric layer 24, typically a BPSG layer, is formed over the transistor structures to isolate and protect transistors 20, 22. Contact openings are formed in the BPSG layer 24 to allow conductive contacts to be made to the diffusion regions and the polysilicon gates (not shown). In the present illustration, tungsten-filled contacts 26 are used. Subsequent to the contact formation, the first metal layer 28 (Metal1) is formed on the top of the BPSG layer 24 to electrically interconnect the transistors to form the desired circuitry.

After the metal1 layer 28 is formed, a dielectric layer 30 is formed to isolate and protect the conductive traces thus formed on the metal1 layer. Dielectric layer 30 is also referred to as an interlevel dielectric layer and is typically a silicon oxide layer. Where needed, via openings are formed in the dielectric layer 30 to allow an overlying metal layer 32 (the metal2 layer) to make electrical contact with the metal1 layer. In the present illustration, tungsten-filled vias 34 are used. Then, the entire surface of the integrated circuit 10 is covered with a passivation layer 36. The passivation layer 36 typically includes two dielectric layers—a bottom oxide layer 38 and a top nitride (or oxynitride) layer 40. The oxide passivation layer 38 has a typical thickness of 6000 Å and the nitride passivation layer 40 has a typical thickness of 5000 Å. The first metal layer (metal1) has a typical thickness of 0.8 μm and the second metal layer (metal2) has a typical thickness of 1.5 μm.

Hitherto, the various structures formed in integrated circuit 10 are conventional. It is imperative to note that the MOP capacitor of the present invention be formed on any type of integrated circuits and the exact structure of the underlying devices in the integrated circuit is not critical to the practice of the present invention. Thus, the transistor, contact and via structures of integrated circuit 10 shown in FIG. 1 are illustrative only. The MOP capacitor of the present invention can be formed in integrated circuits using any other transistor, such as bipolar transistors, and any other contact and via structures. The MOS transistors and tungsten contacts and vias in the embodiment shown in FIG. 1 are exemplary only.

The MOP capacitor of the present invention is particularly applicable to integrated circuits that do not use a lot of the second metal layer (metal2) for constructing the integrated circuit. In that case, it is possible to form a large metal pad using the metal2 layer as the bottom plate of the MOP capacitor. For example, a typical switching regulator integrated circuit forms most if its circuitry using just the first metal layer and a very small amount of the second metal layer is required to complete the circuitry. The MOP capacitor can be advantageously applied in this situation to utilize the unused metal2 area to form a large metal pad for the bottom plate of the MOP capacitor, thereby realizing a capacitor with a large capacitance.

In the integrated circuit of FIG. 1, two MOP capacitors 42 and 44 are formed using the metal2 layer 32 as the bottom plate and a metal layer on the top of the passivation layer 36 as the top plate and the passivation layer 36 as the dielectric. The two MOP capacitors 42, 44 have the same construction but have different terminal connections to illustrate the various ways the two conductive plates of the MOP capacitors can be electrically connected in an integrated circuit.

MOP capacitor 42 will be described first. In integrated circuit 10, a metal pad 32b in the metal2 layer 32 is patterned to form the bottom plate of MOP capacitor 42. A metal layer is deposited on the top of the passivation layer 36 and patterned to form metal pads 46a and 46b. Metal pad 46b is the top plate of MOP capacitor 42. Metal pads 32b and 46b are positioned in direct vertical alignment to each other so that with the passivation layer 36 sandwiched between the two metal pads, a capacitor is formed. Metal pad 32b and metal pad 46b have an area indicative of the desired capacitance for MOP capacitor 42. In the present embodiment, MOP capacitor 42 is intended to be a high voltage capacitor and thus the capacitor has a large area to achieve a sufficiently high capacitance value.

In the present embodiment, metal pad 32b is made slightly smaller than metal pad 46b at one corner to accommodate an electrical connection for the top plate of the capacitor. Specifically, a metal interconnect (or a “metal via”) 48b is formed in the passivation layer to electrically connect metal pad 46b to a metal line 32c formed in the metal2 layer 32. Metal via 48b can be tungsten filled or aluminum filled. By providing metal via 48b and metal line 32c, the top plate of the MOP capacitor can thus be electrically connected to circuitry on integrated circuit 10 as desired.

The position of metal via 46b and metal line 32c in FIG. 1 is illustrative only. One of ordinary skill in the art would appreciate that other configurations can be used to provide an electrical connection between the metal pad 46b to the circuitry below the passivation layer 36. For example, an extension can be formed in metal pad 46b to allow the metal via 48b to be formed off the side of the metal pad so that metal pads 32b and 46b can have the same size and geometry.

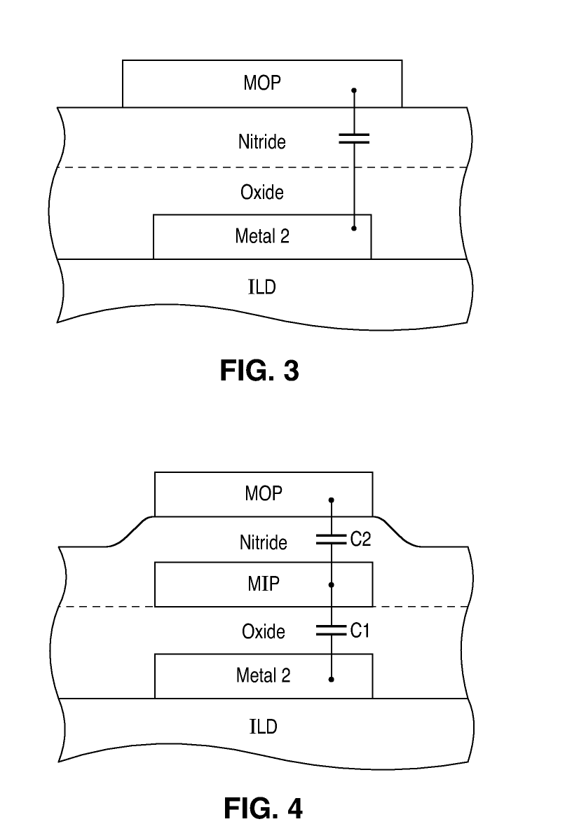

As thus configured, MOP capacitor 42 is formed using a metal pad 46b on the top of the passivation layer and a metal pad 32b that is underneath the passivation layer with the passivation layer as the dielectric. FIG. 3 is a cross-sectional view of the metal-on-passivation capacitor structure according to one embodiment of the present invention. A large capacitance value in MOP capacitor 42 can be realized because of the passivation layer, including the silicon nitride layer, has a high dielectric constant.

Integrated circuit 10 includes a second MOP capacitor 44. A metal pad 32a in the metal2 layer 32 is patterned to form the bottom plate of MOP capacitor 44. Metal pad 46b formed on the top of the passivation layer 36 is the top plate of MOP capacitor 44. Metal pads 32a and 46a are positioned in direct vertical alignment to each other so that with the passivation layer 36 sandwiched between the two metal pads, a capacitor is formed. Metal pad 32a and metal pad 46a have an area indicative of the desired capacitance for MOP capacitor 44. In the present embodiment, MOP capacitor 44 is intended to have a smaller capacitance value than MOP capacitor 42. Thus, the area of metal pads 32a and 46a is smaller than that of metal pads 32b and 46b.

MOP capacitor 44 illustrates another method for forming electrical connections to the capacitor conductive plates. In the present embodiment, the bottom plate (metal pad 32a) of MOP capacitor 44 is connected through vias and metal1 layer to circuitry of the integrated circuit. The top plate (metal pad 46a) on top of the passivation layer is not connected to the internal circuitry of the integrated circuit but rather can be connected to terminals external to the integrated circuit, such as through a bond wire 50.

As thus configured, MOP capacitors 42 and 44 are formed using metal pad 46b and 46a, respectively, that are formed on the top of the passivation layer 36. Metal pads 46a and 46b are exposed metal layer of integrated circuit 10. That is, integrated circuit 10 is not subjected to any further fabrication processes and metal pads 46a and 46b are exposed to the environment except for packaging material that may be applied when integrated circuit 10 is assembled in an electronic device.

In the present description, a passivation layer refers specifically to the topmost dielectric layer that is used in an integrated circuit to insulate and passivate the active circuitry on the integrated circuit. The passivation layer can be formed using silicon oxide, silicon nitride, silicon oxynitride, polyimide or other materials or a combination of these layers. The metal-on-passivation capacitor of the present invention includes one conductive plate that is formed on the top of the passivation layer and uses the passivation layer as the dielectric.

In one embodiment, a 100 pf MOP capacitor is formed on an integrated circuit having a die size of 64×74 mil². The metal pads have areas of about 62×62 mils (3840 mil²) which cover most of the active area of the integrated circuit. The 100 pf capacitance is obtained by assuming a passivation nitride thickness of 5000 Å, a passivation oxide thickness of 6000 Å. The nitride capacitance is assumed to be about 1.30×10−4 pF/μ² and the oxide capacitance is assumed to be about 0.57×10−4 pF/μ². Thus, the composite passivation capacitance is about 0.4×10−4 pF/μ².

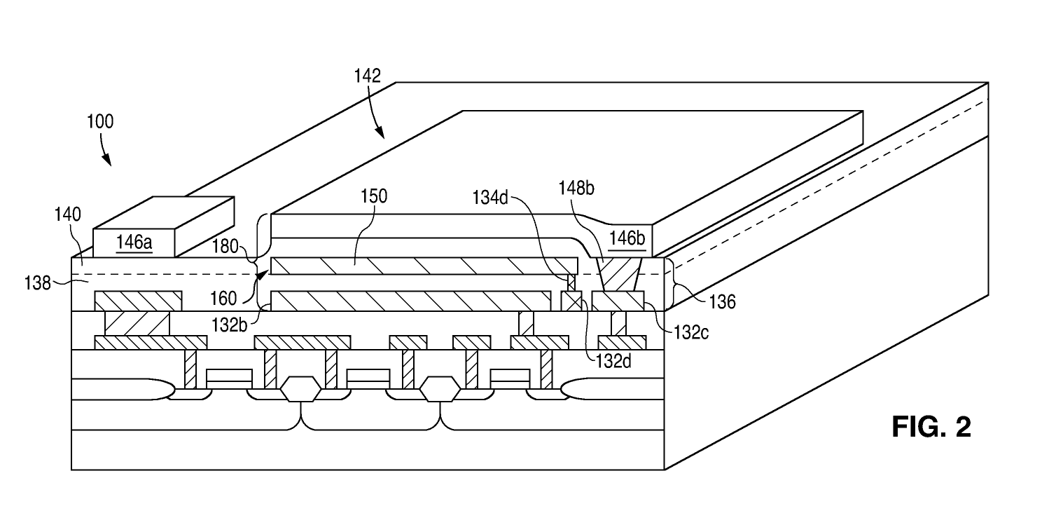

FIG. 2 is a perspective cross-sectional view of a semiconductor integrated circuit incorporating a metal-on-passivation capacitor and a metal-in-passivation capacitor according to an alternate embodiment of the present invention. Referring to FIG. 2, integrated circuit 100 includes a passivation sandwich capacitor 180 formed by a metal-on-passivation (MOP) capacitor 142 and a metal-in-passivation (MIP) capacitor 160. The basic structure of integrated circuit 100 is similar to integrated circuit 10 of FIG. 1 and layers and structure in FIG. 2 that are the same as those in FIG. 1 will not be further described.

First, the MIP capacitor 160 is formed by using a metal pad 132b formed on the metal2 layer as the bottom plate of the capacitor. Then, a first passivation dielectric layer 138 is deposited. Typically, the first passivation dielectric layer 138 is an oxide layer. Then, a metal layer is deposited and patterned to form a metal pad 150. Metal pad 150 is a thin metal layer, as 500-6000 Å, so as to not affect planarity of the integrated circuit. The metal pad can be formed using any metal such as aluminum, aluminum alloy, copper, copper alloy, titanium (Ti), titanium nitride (TiN), titanium tungsten (TiW) and other suitable metals. A metal via 134d can be formed in the first passivation dielectric layer 138 to form an electrical connection from metal pad 150 to an underlying metal pad 132d to allow metal pad 150 to be connected to electrical circuitry on the integrated circuit.

Metal pad 150 is in vertical alignment with metal pad 132b and together form the top and bottom plates of the MIP capacitor 160 with the first passivation dielectric layer 138 serving as the dielectric layer of the MIP capacitor 160. FIG. 4 is a cross-sectional view of the metal-on-passivation capacitor and metal-in-passivation capacitor structure according to one embodiment of the present invention. The MIP capacitor 160 is illustrated in FIG. 4 as capacitor C1 between the metal-in-passivation and the metal pad formed in the metal2 layer.

Subsequent to the formation of metal pad 150, a second passivation dielectric layer 140 is deposited. Typically, the second passivation dielectric layer 140 is a silicon nitride layer, a silicon oxynitride layer or nitride over a thin oxide layer so nitride is not in direct contact with certain metals. The first and second passivation dielectric layers 138, 140 together form the passivation layer 136. Finally, a metal layer is deposited on the top of the passivation layer 136 and patterned to form metal pads 146a and 146b.

Metal pad 146b forms the top plate of MOP capacitor 142. Metal pads 150 and 146b are positioned in direct vertical alignment to each other so that with the second passivation dielectric layer 140 sandwiched between the two metal pads, a capacitor is formed. In the present embodiment, a metal via 148 is formed in the passivation layer 136 to allow metal pad 146b to make an electrical connection to the underlying metal2 layer. As discussed above, other means for providing an electrical connection to the metal-on-passivation metal pad are possible. The MOP capacitor 142 thus formed is illustrated in FIG. 4 as capacitor C2 between the metal-in-passivation and the metal-on-passivation.

The passivation sandwich capacitor 180 requires an additional masking step between first and second passivation dielectric deposition. However, the passivation sandwich capacitor 180 realizes a stacked capacitor structure as shown in FIG. 4 where the two capacitors C1 and C2 can be electrically connected to be in series or in parallel.

The metal layer used to form the metal-on-passivation and metal-in-passivation can be formed using aluminum, aluminum alloy, copper, copper alloy, titanium (Ti), titanium nitride (TiN), titanium tungsten (TiW) and other metals typically used in semiconductor processing. The exact thickness of the metal layer forming the metal-on-passivation and metal-in-passivation is not critical but should be on the order of the thickness of the topmost metal layer of the integrated circuit. For example, a typical thickness for the second metal layer (metal2) is 1.5 μm. The metal-on-passivation and the metal-in-passivation metal layer can have a thickness on the order of 1.5 μm.

Furthermore, in the above description, the bottom plate is formed using the second metal layer (metal2) of the integrated circuit. This is illustrative only and is not intended to limit the formation of the MOP or MIP capacitor using only the metal2 layer. As is well known in the art, integrated circuits are built using multiple metal layers with the topmost layer being passivated by the passivation layer. The bottom plate of either MOP or MIP capacitor of the present invention can be formed using the topmost metal layer of the integrated circuit passivated by the passivation layer.

The above detailed descriptions are provided to illustrate specific embodiments of the present invention and are not intended to be limiting. Numerous modifications and variations within the scope of the present invention are possible. The present invention is defined by the appended claims.

I claim:

1. A capacitor formed in an integrated circuit, the integrated circuit being fabricated using a fabrication process having multiple metal layers with the topmost metal layer being passivated by a passivation layer, the capacitor comprising:
a first metal pad formed underneath the passivation layer using the topmost metal layer of the integrated circuit, the first metal pad forming the first conductive plate of the capacitor; and
a second metal pad formed on the top of the passivation layer, the second metal pad being in vertical alignment with the first metal pad, the second metal pad forming the second conductive plate of the capacitor, the second metal pad being formed without an overlying passivation layer,
wherein the passivation layer sandwiched between the first metal pad and the second metal pad forms the dielectric of the capacitor.

2. The capacitor of claim 1, wherein the second metal pad is formed using a material selected from aluminum, aluminum alloy, copper, copper alloy, titanium (Ti), titanium nitride (TiN), titanium tungsten (TiW).

3. The capacitor of claim 1, further comprising:
a third metal pad formed underneath the passivation layer using the topmost metal layer of the integrated circuit;
a metal interconnect formed in the passivation layer and electrically connecting the second metal pad to the third metal pad.

4. The capacitor of claim 1, wherein the passivation layer comprises a first dielectric layer and a second dielectric layer formed over the first dielectric layer.

5. The capacitor of claim 4, wherein the first dielectric layer comprises a silicon oxide layer and the second dielectric layer comprises a silicon nitride layer.

6. The capacitor of claim 4, wherein the first dielectric layer comprises a silicon oxide layer and the second dielectric layer comprises a silicon oxynitride layer.

7. The capacitor of claim 4, further comprising:
a fourth metal pad formed between the first dielectric layer and the second dielectric layer, the fourth metal pad being in vertical alignment with the first and second metal pads,
wherein the capacitor comprises a stacked capacitor including a first capacitor formed by the first metal pad and the fourth metal pad and the first dielectric layer sandwiched therebetween and a second capacitor formed by the fourth metal pad and the second metal pad and the second dielectric layer sandwiched therebetween.

8. The capacitor of claim 7, wherein the first and second capacitors are electrically connected in series.

9. The capacitor of claim 7, wherein the first and second capacitors are electrically connected in parallel.

10. The capacitor of claim 7, wherein the second metal pad and the fourth metal pad are formed using a material selected from aluminum, aluminum alloy, copper, copper alloy, titanium (Ti), titanium nitride (TiN), titanium tungsten (TiW).

11. The capacitor of claim 7, further comprising:
a fifth metal pad formed underneath the passivation layer using the topmost metal layer of the integrated circuit;
a metal interconnect formed in the first dielectric layer and electrically connecting the fourth metal pad to the fifth metal pad.

12. The capacitor of claim 1, wherein the second metal pad is disposed to accept a bond wire.

13. The capacitor of claim 1, wherein the second metal pad has a thickness of about 1.5 μm.

14. The capacitor of claim 7, wherein the fourth metal pad has a thickness of about 500-6000 Å.
